(19) United States
(12) Patent Application Publication
(10) Pub. No.: US 2024/0145490 A1
(43) Pub. Date: May 2, 2024

(54) ELECTRO-OPTICAL DEVICE AND ELECTRONIC APPARATUS

(71) Applicant: SEIKO EPSON CORPORATION, Tokyo (JP)

(72) Inventor: Masahito YOSHII, CHITOSE-SHI (JP)

(73) Assignee: SEIKO EPSON CORPORATION, Tokyo (JP)

(21) Appl. No.: 18/496,900

(22) Filed: Oct. 29, 2023

(30) Foreign Application Priority Data
Oct. 31, 2022 (JP) 2022-174169

(51) Int. Cl. H01L 27/12

(52) U.S. Cl. CPC H01L 27/124; G02F 1/1368

(57) ABSTRACT

Provided are a transistor, a pixel electrode provided corresponding to the transistor, a relay layer provided at a layer between the transistor and the pixel electrode and including, in this order from the pixel electrode side, a metal material layer containing a metal material, an insulating material layer containing an insulating material, and a metal material layer containing a metal material, and a lens layer provided at a layer between the relay layer and the pixel electrode and including a contact hole for electrically connecting the relay layer and the pixel electrode, and in the relay layer, portions of the metal material layer and the insulating material layer overlapping the contact hole are removed.

The present application is based on, and claims priority from JP Application Serial Number 2022-174169, filed Oct. 31, 2022, the disclosure of which is hereby incorporated by reference herein in its entirety.

### BACKGROUND

### 1. Technical Field

The present disclosure relates to an electro-optical device and an electronic apparatus including an electro-optical device.

### 2. Related Art

JP 2021-167884 A describes an electro-optical device including a pixel electrode formed at a substrate body of an element substrate, a transistor formed between the pixel electrode and a substrate body, a lens formed between the pixel electrode and the transistor, and a connecting member provided to extend through a layer at which the lens is provided, and electrically connected to the pixel electrode.

Since a thickness of the layer at which the lens is provided between the pixel electrode and the transistor is large, it is necessary to form a contact hole having a high aspect ratio at the layer at which the lens is provided in order to provide the connecting member extending through the layer at which the lens is provided.

Then, since a process of forming the contact hole having a high aspect ratio at the thick layer provided with the lens requires a long time for etching, a hard mask containing a metal material that can withstand etching for a long time may be used as an etching mask.

However, when the hard mask is used, there is a problem in that a conductive layer exposed at a bottom of the contact hole disappears together with the hard mask when the hard mask is removed.

### SUMMARY

An electro-optical device according to an aspect of the present application includes a transistor, a pixel electrode provided corresponding to the transistor, a first conductive layer provided at a layer between the transistor and the pixel electrode, and including a first layer containing a metal material, a second layer containing an insulating material, and a third layer containing a metal material in this order from the pixel electrode side, and a lens layer provided at a layer between the first conductive layer and the pixel electrode, and including a first contact hole for electrically connecting the first conductive layer and the pixel electrode, wherein in the first conductive layer, portions of the first layer and the second layer overlapping the first contact hole are removed.

An electronic apparatus according to an aspect of the present disclosure includes the electro-optical device described above.

A method of manufacturing an electro-optical device according to an aspect of the present application includes forming a first conductive layer, forming a lens layer at the first conductive layer, forming a mask containing a metal material at the lens layer, forming a first contact hole at the lens layer via the mask, and removing the mask, wherein the first conductive layer includes a first layer containing a metal material, a second layer containing an insulating material having a lower etching rate with respect to an etchant for removing the mask than that of the mask, and a third layer containing a metal material, and during removing the mask, the first layer and the second layer are partially removed.

### BRIEF DESCRIPTION OF THE DRAWINGS

FIG. 1 is a plan view of an electro-optical device according to Embodiment 1.

FIG. 2 is a cross-sectional view of the electro-optical device taken along line II-II in FIG. 1.

FIG. 3 is an equivalent circuit diagram illustrating an electrical configuration of an element substrate.

FIG. 4 is an explanatory diagram illustrating a cross-sectional structure of a display region of the element substrate.

FIG. 5 is a plan view illustrating a part of the display region of the element substrate.

FIG. 6 is a cross-sectional view taken along line VI-VI in FIG. 5.

FIG. 7 is a flowchart illustrating a method of manufacturing an optical functional layer.

FIG. 8 is a flowchart illustrating details of step S50 in FIG. 7.

FIG. 9 is a flowchart illustrating details of step S80 in FIG. 7.

FIG. 10 is a cross-sectional view illustrating an aspect in a manufacturing process.

FIG. 11 is a cross-sectional view illustrating an aspect in a manufacturing process.

FIG. 12 is a cross-sectional view illustrating an aspect in a manufacturing process.

FIG. 13 is a cross-sectional view illustrating an aspect in a manufacturing process.

FIG. 14 is a cross-sectional view of an electro-optical device according to Modification 2.

FIG. 15 is a cross-sectional view of an electro-optical device according to Embodiment 2.

FIG. 16 is a flowchart illustrating details of step S50 in FIG. 7.

FIG. 17A is a cross-sectional view illustrating an aspect in a manufacturing process.

FIG. 17B is a plan view illustrating an aspect in a manufacturing process.

FIG. 18 is a schematic diagram illustrating an example of an electronic apparatus according to Embodiment 3.

### DESCRIPTION OF EMBODIMENTS

Embodiments of the present disclosure will be described below with reference to the accompanying drawings.

In the following drawings, the dimensions of some components may be scaled differently for ease of understanding for the components.

Further, hereinafter, for convenience of explanation, the description will be made appropriately using an X-axis, a Y-axis and a Z-axis orthogonal to each other. Also, one direction along the X-axis is referred to as an X1 direction, and a direction opposite to the X1 direction is referred to as an X2 direction. Similarly, one direction along the Y-axis is referred to as a Y1 direction, and a direction opposite to the Y1 direction is referred to as a Y2 direction. One direction along the Z-axis is referred to as a Z1 direction, and a direction opposite to the Z1 direction is referred to as a Z2 direction. Further, in the following description, viewing in the Z1 direction or the Z2 direction is referred to as “plan view”, and viewing in a direction perpendicular to a cross-section including the Z-axis is referred to as “cross-sectional view”.

Further, in the following description, for example, with respect to a substrate, the description “on the substrate” means any of a case in which the element is disposed on the substrate in contact therewith, a case in which the element is disposed on the substrate with another structure interposed therebetween, and a case in which the element is partially disposed on the substrate in contact therewith and partially disposed with another structure interposed therebetween. In addition, the description of an upper surface of a certain configuration indicates a surface of the configuration on the side on the Z1 direction side, for example, an “upper surface of a light transmitting layer” indicates a surface of the light transmitting layer on the side on the Z1 direction side. In addition, the description of a lower surface of a certain configuration indicates a surface of the configuration on the side in the Z2 direction, for example, a “lower surface of a contact plug” indicates a surface of the contact plug on the side in the Z2 direction.

### 1. Embodiment 1

In the embodiment, as an electro-optical device, an active drive liquid crystal device having a thin film transistor (TFT) being a switching element for each of pixels will be described as an example. The liquid crystal device is used, for example, as a light modulation device in a projection type display device as an electronic apparatus which will be described below.

1.1. Outline of Structure of Liquid Crystal Device

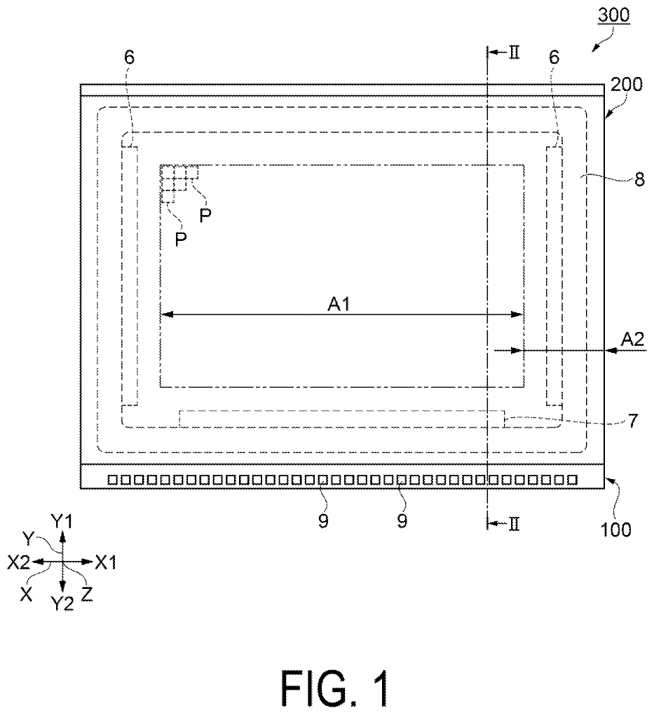

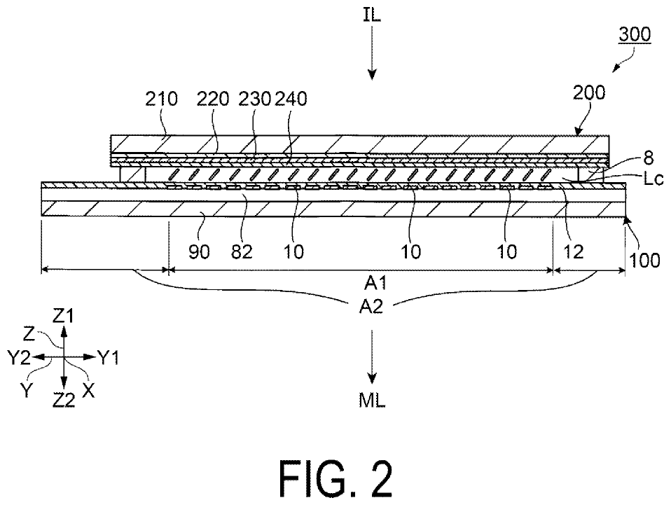

A structure of a liquid crystal device as an electro-optical device according to the embodiment will be described with reference to FIGS. 1 and 2. FIG. 1 is a plan view of an electro-optical device according to Embodiment 1, and illustrates a schematic plan configuration of a transmissive liquid crystal device 300 as the electro-optical device. FIG. 2 is a cross-sectional view of the electro-optical device taken along line II-II in FIG. 1, and illustrates a schematic cross-sectional configuration of the liquid crystal device 300.

As illustrated in FIGS. 1 and 2, the liquid crystal device 300 includes an element substrate 100 having a light transmitting property, a counter substrate 200 having a light transmitting property, a sealing member 8 provided in a frame shape, and a liquid crystal layer Lc. The term “light transmitting property” refers to transparency to visible light, and means that a transmittance of visible light may be 50% or more.

The liquid crystal device 300 includes a display region A1 for displaying an image and an outer region A2 located outside the display region A1 in plan view. A plurality of pixels P arranged in a matrix pattern are provided in the display region A1. Although a shape of the liquid crystal device 300 illustrated in FIG. 1 is quadrangular, it may be circular, for example.

As illustrated in FIG. 2, the element substrate 100 and the counter substrate 200 are disposed with the liquid crystal layer Lc interposed therebetween.

In the embodiment, the counter substrate 200 is disposed on a light incident side of the liquid crystal layer Lc, and the element substrate 100 is disposed on a light emitting side of the liquid crystal layer Lc. Incident light IL incident on the counter substrate 200 is modulated by the liquid crystal layer Lc and is emitted from the element substrate 100 as modulated light ML.

The element substrate 100 includes a base body 90, a plurality of interlayer insulating layers including an interlayer insulating layer 82, a pixel electrode 10, and an alignment film 12. Although not illustrated, a lens layer 34 which will be described below is provided between the pixel electrode 10 and the interlayer insulating layer 82.

The base body 90 is a flat plate having a light transmitting property and an insulation property. The base body 90 is, for example, a glass substrate or a quartz substrate. The transistor 1 which will be described below is disposed between the plurality of interlayer insulating layers.

The pixel electrode 10 has a light transmitting property. The pixel electrode 10 is formed of a transparent conductive material such as indium tin oxide (ITO), indium zinc oxide (IZO) and fluorine-doped tin oxide (FTO). A thickness-wise direction of the pixel electrode 10 coincides with the Z1 direction or the Z2 direction.

The alignment film 12 has a light transmitting property and an insulation property. The alignment film 12 aligns liquid crystal molecules of the liquid crystal layer Lc. Examples of a material of the alignment film 12 include oxide silicon (SiO₂) and polyimide.

The counter substrate 200 is a substrate disposed to face the element substrate 100. The counter substrate 200 includes a base body 210, an insulating layer 220, a common electrode 230 and an alignment film 240.

The base body 210 is a flat plate having a light transmitting property and an insulation property. The base body 210 is, for example, a glass substrate or a quartz substrate.

The insulating layer 220 has a light transmitting property and an insulating property. A material of the insulating layer 220 is an inorganic material such as oxide silicon.

The common electrode 230 is an electrode disposed to face a plurality of the pixel electrodes 10, and is also referred to as a counter electrode. The common electrode 230 includes a transparent conductive material such as ITO, IZO and FTO. The common electrode 230 and the pixel electrode 10 apply an electric field to the liquid crystal layer Lc.

The alignment film 240 has a light transmitting property and an insulating property.

The sealing member 8 is disposed between the element substrate 100 and the counter substrate 200. The sealing member 8 is formed using an adhesive containing various types of curable resins such as epoxy resin, for example. The sealing member 8 may include a gap material made of an inorganic material such as glass.

The liquid crystal layer Lc is disposed in a region surrounded by the element substrate 100, the counter substrate 200, and the sealing member 8. The liquid crystal layer Lc is an electro-optical layer of which optical characteristics change in accordance with an electric field caused by the pixel electrode 10 and the common electrode 230. The liquid crystal layer Lc contains liquid crystal molecules having positive or negative dielectric anisotropy. The alignment of the liquid crystal molecules changes according to an electric field applied to the liquid crystal layer Lc. The liquid crystal layer Lc modulates the incident light IL in accordance with the applied electric field.

As illustrated in FIG. 1, a plurality of scanning line driving circuits 6, a data line driving circuit 7 and a plurality of external terminals 9 are disposed in the outer region A2 of the element substrate 100. Some of the plurality of external terminals 9 are connected to the scanning line driving circuit 6 or the data line driving circuit 7 via wiring (not illustrated). Further, the plurality of external terminals 9 include a terminal to which a common potential is applied from the outside.

1.2. Electrical Configuration of Element Substrate

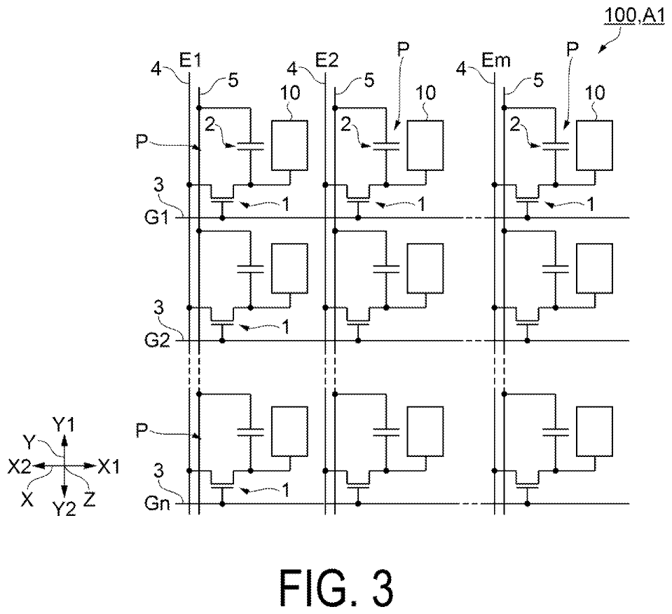

FIG. 3 is an equivalent circuit diagram illustrating an electrical configuration of the element substrate.

As illustrated in FIG. 3, a plurality of transistors 1 as switching elements, n scanning lines 3, m data lines 4, and m capacitance lines 5 are provided in the display region A1 of the element substrate 100. Both n and m are integers of 2 or greater. The transistors 1 are disposed corresponding to intersections of the n scanning lines 3 and the m data lines 4, respectively.

Each of the n scanning lines 3 extends in the X1 direction, and the n scanning lines 3 are arranged at equal intervals in the Y1 direction. Each of the n scanning lines 3 is electrically connected to a gate electrode of the corresponding transistor 1. The n scanning lines 3 are electrically connected to the scanning line driving circuit 6 illustrated in FIG. 1.

The scanning line driving circuit 6 line-sequentially supplies scanning signals G1, G2, . . . , and Gn to 1st to n-th scanning lines 3.

Each of the m data lines 4 extends in the Y1 direction, and the m data lines 4 are arranged at equal intervals in the X1 direction. The m data lines 4 are electrically connected to source regions of the corresponding plurality of transistor 1, respectively. The m data lines 4 are electrically connected to the data line driving circuit 7 illustrated in FIG. 1.

The data line driving circuit 7 supplies image signals E1, E2, . . . , and Em to 1st to m-th data lines 4.

The n scanning lines 3 and the m data lines 4 are electrically insulated from each other and are disposed in a lattice-like pattern in plan view. A region surrounded by two adjacent scanning lines 3 and two adjacent data lines 4 corresponds to a pixel P.

The pixel electrode 10 is provided for each of the pixels P. The pixel electrode 10 is electrically connected to a drain of the transistor 1.

Each of the m capacitance lines 5 extends in the Y1 direction, and the m capacitance lines 5 are arranged at equal intervals in the X1 direction. In addition, the m capacitance lines 5 are electrically insulated from the m data lines 4 and the n scanning lines 3 and are disposed with gaps therebetween. A fixed potential such as a common potential or a ground potential is applied to each of the capacitance lines 5.

One electrode of a capacitance element 2 is electrically connected to the capacitance line 5. Another electrode of the capacitance element 2 is electrically connected to the pixel electrode 10 and holds a potential of an image signal supplied to the pixel electrode 10.

1.3. Cross-Sectional Structure of Display Region of Element Substrate

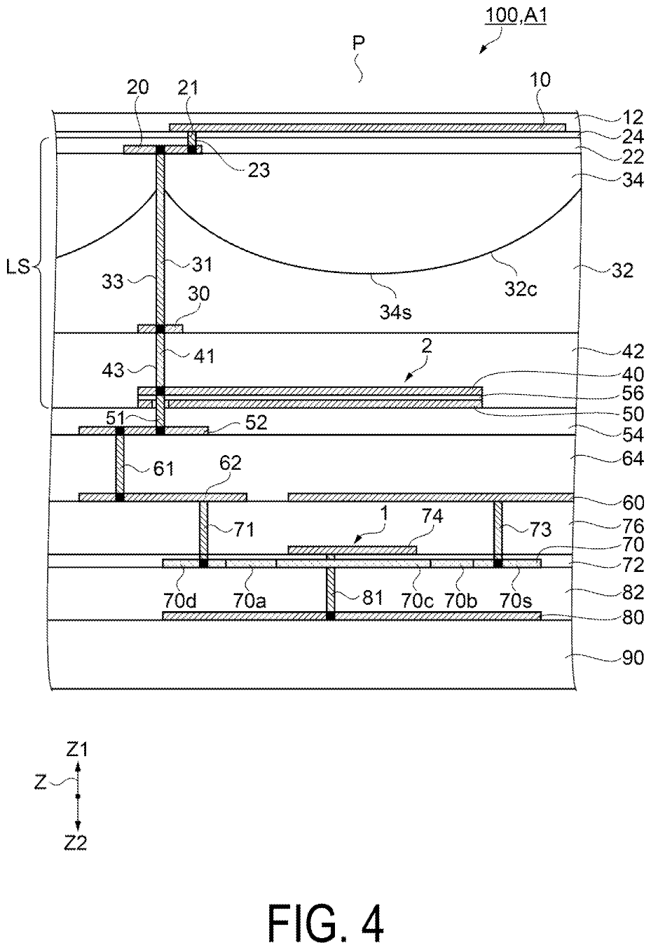

FIG. 4 is an explanatory diagram illustrating a cross-sectional structure of the display region of the element substrate, and illustrates a cross-sectional structure of the pixel P provided in the display region A1.

As illustrated in FIG. 4, in the display region A1, the element substrate 100 has a cross-sectional structure in which insulating or conductive functional layers or functional films are stacked at the base body 90.

A light shielding layer 80 is disposed between the base body 90 and the interlayer insulating layer 82.

The light shielding layer 80 is formed of a conductive material having a light shielding property.

As the conductive material having a light shielding property, for example, a metal such as tungsten (W), titanium (Ti), chromium (Cr), iron (Fe), or aluminum (AL), a metal nitride or a metal silicide can be used. The same applies hereinafter.

The light shielding layer 80 constitutes a part of the scanning line 3. The term “light shielding property” means a light shielding property against visible light, means that a transmittance of visible light may be less than 50%, and may be 10% or less.

The interlayer insulating layer 82 has a light transmitting property and an insulating property. The interlayer insulating layer 82 is formed of, for example, an inorganic material such as oxide silicon (SiO₂).

The transistor 1 is disposed at the interlayer insulating layer 82.

The transistor 1 includes a semiconductor layer 70 having a lightly doped drain (LDD) structure, a gate electrode 74, and a gate insulating layer 72.

The semiconductor layer 70 has a drain region 70d, an LDD region 70a, a channel region 70c, an LDD region 70b, and a source region 70s.

The channel region 70c is located between the source region 70s and the drain region 70d. The LDD region 70b is located between the channel region 70c and the source region 70s. The LDD region 70a is located between the channel region 70c and the drain region 70d.

The semiconductor layer 70 is made of, for example, polysilicon, and the regions other than the channel region 70c are doped with an impurity for increasing conductivity. An impurity concentration in the LDD region 70b and the LDD region 70a is lower than an impurity concentration in the source region 70s and the drain region 70d.

The gate electrode 74 is provided at the semiconductor layer 70 via the gate insulating layer 72. The gate electrode 74 overlaps the channel region 70c of the semiconductor layer 70.

The gate electrode 74 is formed by, for example, doping polysilicon with an impurity that increases conductivity. The gate electrode 74 may be formed using a conductive material such as a metal, a metal silicide or a metal compound.

The gate insulating layer 72 is made of, for example, a film of oxide silicon formed by a thermal oxidation method, a chemical vapor deposition (CVD) method or the like.

The gate electrode 74 and the light shielding layer 80 are electrically connected through a contact hole 81 passing through the gate insulating layer 72 and the interlayer insulating layer 82.

A conductive layer 60 and a relay layer 62 are provided at the transistor 1 via an interlayer insulating layer 76.

The conductive layer 60 and the relay layer 62 are provided at the same layer and are formed of a light shielding conductive material. The interlayer insulating layer 76 is formed of the same material as that of the interlayer insulating layer 82.

The conductive layer 60 constitutes a part of the data line 4. The conductive layer 60 is electrically connected to the source region 70s of the semiconductor layer 70 via a contact hole 73 passing through the interlayer insulating layer 76.

The relay layer 62 is electrically connected to the drain region 70d of the semiconductor layer 70 via a contact hole 71 passing through the interlayer insulating layer 76.

An interlayer insulating layer 64 is provided at the conductive layer 60 and the relay layer 62, and a relay layer 52 is provided at the interlayer insulating layer 64. The relay layer 52 is formed of a light shielding conductive material. The interlayer insulating layer 64 is formed of the same material as that of the interlayer insulating layer 82.

The relay layer 52 is electrically connected to the relay layer 62 through a contact hole 61 passing through the interlayer insulating layer 64.

The capacitance element 2 is provided at the relay layer 52 via an interlayer insulating layer 54.

The capacitance element 2 includes a capacitance electrode 50 provided on the base body 90 side, a capacitance electrode 40 provided on the pixel electrode 10 side, and a dielectric layer 56 provided between the capacitance electrode 50 and the capacitance electrode 40. Both the capacitance electrode 40 and the capacitance electrode 50 are formed of a light shielding conductive material. The interlayer insulating layer 54 is formed of the same material as that of the interlayer insulating layer 82.

The capacitance electrode 50 constitutes a part of the capacitance line 5.

The capacitance electrode 40 is electrically connected to the relay layer 52 via a contact hole 51 passing through the interlayer insulating layer 54. Thus, the capacitance electrode 40 is electrically connected to the drain region 70d of the transistor 1.

An optical functional layer LS including the lens layer 34 is provided between the capacitance electrode 40 and the pixel electrode 10.

The optical functional layer LS is provided to curb light amount loss. Specifically, an optical path of transmitted light is adjusted so that the transmitted light that has passed through the pixel electrode 10 is prevented from colliding with a light shielding material layer such as the data line 4 or the capacitance line 5 and causing loss. The optical functional layer LS includes a light transmitting layer 42, a light transmitting layer 32, the lens layer 34, a light transmitting layer 22 and a protective layer 24.

The light transmitting layer 42 is an optical path length adjusting layer called a path layer for adjusting an optical path length. The light transmitting layer 42 is formed of an inorganic material such as oxide silicon. Further, an upper surface of the light transmitting layer 42 is planarized by chemical mechanical polishing (CMP) or the like.

The light transmitting layer 32 is a lens forming layer at which a concave portion 32c serving as a lens surface 34s of the lens layer 34 is provided, and is formed of an inorganic material such as oxide silicon similarly to the light transmitting layer 42.

The concave portion 32c of the light transmitting layer 32 is formed by etching the light transmitting layer 32 after forming the light transmitting layer 32.

The lens layer 34 is provided on the light transmitting layer 32. The lens layer 34 is formed of an inorganic material having a refractive index different from that of the light transmitting layer 32, for example, silicon oxynitride (SiON). The lens layer 34 is planarized by CMP or the like after silicon oxynitride is formed as film as to fill the concave portion 32c.

The light transmitting layer 22 is provided on the lens layer 34. The light transmitting layer 22 is an optical path length adjusting layer and is formed of an inorganic material such as oxide silicon similarly to the light transmitting layer 42. A thickness of the light transmitting layer 22 is less than a thickness of the light transmitting layer 32.

The protective layer 24 is provided at the light transmitting layer 22. The protective layer 24 is made of, for example, an inorganic material having light transmitting property and hygroscopicity such as borosilicate glass (BSG).

The pixel electrode 10 is provided at the protective layer 24. The alignment film 12 is provided at the pixel electrode 10.

The pixel electrode 10 and the capacitance electrode 40 are electrically connected to each other, via a pixel contact plug 21, a relay layer 20, a contact plug 31, a relay layer 30, and a contact plug 41. Thus, the pixel electrode 10 is electrically connected to the drain region 70d of the transistor 1.

A contact hole 23 extending through the light transmitting layer 22 and the protective layer 24 is provided between the pixel electrode 10 and the relay layer 20.

The contact hole 23 is provided to electrically connect the pixel electrode 10 and the relay layer 20, and the pixel contact plug 21 as a connecting member is provided at the contact hole 23. The pixel contact plug 21 is formed of a conductive material having a light shielding property such as tungsten.

When tungsten is used as a material for the pixel contact plug 21, the relay layer 20 is formed of a material, for example, titanium nitride (TiN) or the like, which provides good electrical conduction with tungsten.

A contact hole 33 extending through the lens layer 34 and the light transmitting layer 32 is provided between the relay layer 20 and the relay layer 30.

The contact hole 33 is provided to electrically connect the relay layer 20 and the relay layer 30, and the contact plug 31 as a connecting member is provided at the contact hole 33. The contact plug 31 is formed of a conductive material having a light shielding property such as tungsten.

When tungsten is used as a material for the contact plug 31, the relay layer 30 is formed of a material, for example, titanium nitride or the like, which provides good electrical conduction with tungsten.

A contact hole 43 extending through the light transmitting layer 42 is provided between the relay layer 30 and the capacitor electrode 40.

The contact hole 43 is provided to electrically connect the relay layer 30 and the capacitance electrode 40, and the contact plug 41 as a connecting member is provided at the contact hole 43. The contact plug 41 is formed of a conductive material having a light shielding property such as tungsten.

When tungsten is used as a material for the contact plug 41, the capacitance electrode 40 is formed of a material, for example, titanium nitride or the like, which provides good electrical conduction with tungsten.

1.4. Planar Structure of Display Region of Element Substrate

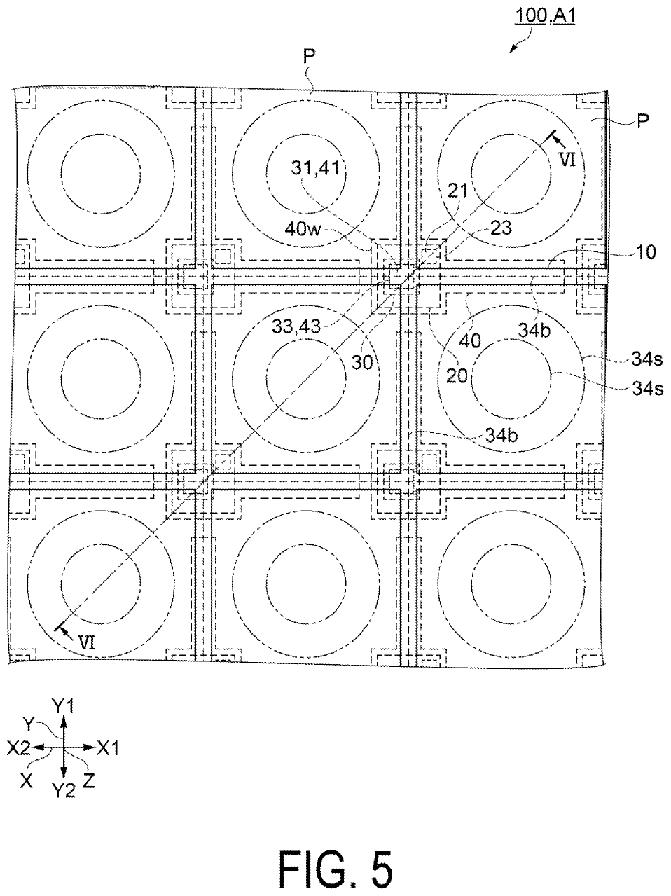

FIG. 5 is a plan view illustrating a part of the display region of the element substrate, and is a view of the display region A1 of the element substrate 100 when seen from the liquid crystal layer Lc side in the Z2 direction. In FIG. 5, the pixel electrode 10 is drawn with a solid line, and a configuration included in the optical functional layer LS provided closer to the base body 90 than the pixel electrode 10 is drawn with a broken line.

In addition, in a plan view illustrated below, a curved surface shape of the lens surface 34s is indicated by a double circle of a two-dot chain line, and a boundary at which the two adjacent lens surfaces 34s are in contact with each other is indicated by a boundary 34b.

The pixel electrodes 10 are disposed in a matrix along the X-axis and the Y-axis.

The pixel contact plug 21 is provided at a position overlapping the pixel electrode 10, in the embodiment, a position overlapping a lower left corner of the drawing of four corners of the pixel electrode 10.

A shape of the relay layer 20 is a rectangle. Four corners of the relay layer 20 are provided to overlap respective corners of four pixel electrodes 10 adjacent in the X2 direction, the Y2 direction, and a diagonal direction of the pixel electrodes 10.

The contact hole 23 and the pixel contact plug 21 are provided at one corner of the four corners of the relay layer 20 in plan view.

The contact hole 33 and the contact plug 31 are provided at a position overlapping the relay layer 20 in plan view, and provided so as to overlap a gap among the four adjacent pixel electrodes 10.

The contact hole 33 and the contact plug 31 are provided at a position not overlapping the contact hole 23 and the pixel contact plug 21 in plan view in the embodiment. In order for the contact plug 31 and the pixel contact plug 21 not to overlap each other, the contact hole 33 and the contact plug 31 are provided at the relay layer 20 to be closer to a corner diagonal to the corner at which the contact hole 23 and the pixel contact plug 21 are provided.

When the contact hole 23 and the pixel contact plug 21 are provided at the position not overlapping the contact hole 33 and the contact plug 31 as described above, film formability of the pixel electrode 10 overlapping the contact hole 23 and the pixel contact plug 21 can be improved as compared with a case in which the contact hole 23 and the pixel contact plug 21 are provided at a position overlapping the contact hole 33 and the contact plug 31.

The relay layer 30 is a rectangle having an area smaller than that of the relay layer 20.

The contact plug 41 is provided at a position overlapping the contact plug 31. More specifically, the contact plug 41 and the contact plug 31 substantially completely overlap each other in plan view.

The capacitance electrode 40 includes a wide portion 40w, an extending portion extending from the wide portion 40w in the X1 direction to overlap the scanning line 3, and an extending portion extending from the wide portion 40w in the Y1 direction to overlap the date line 4.

The wide portion 40w has a size and a shape to overlap an entirety of the relay layer 20 and the relay layer 30 in plan view.

In the embodiment, a place at which the boundary lines 34b intersect overlaps the contact plug 31. This indicates that the contact plug 31 is provided to extend through the lens layer 34.

In the embodiment, a shape of each of the pixel contact plug 21, the contact plug 31 and the contact plug 41 is rectangular in plan view, but is not limited thereto and may be circular.

1.5. Structure of Optical Functional Layer in Display Region of Element Substrate

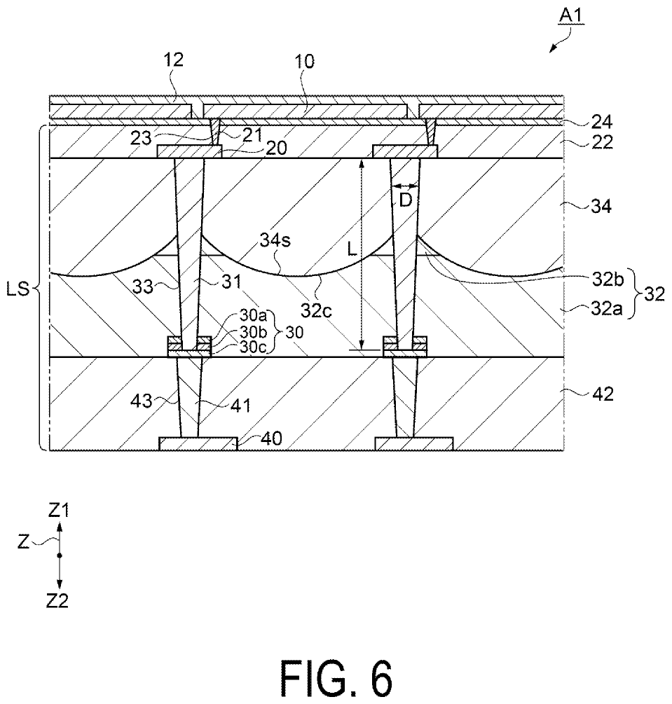

FIG. 6 is a cross-sectional view taken along line VI-VI in FIG. 5 and illustrates a cross-sectional structure of the optical functional layer LS.

The light transmitting layer 32 includes a light transmitting layer 32a and a light transmitting layer 32b.

The light transmitting layer 32 is initially formed to have a thickness of about 7 μm in order to provide the concave portion 32c to be the lens surface 34s of the lens layer 34. Since it is difficult to form a thick bulk layer having a thickness of 7 μm in a single film formation process in terms of process, the light transmitting layer 32 is formed as film separately as the light transmitting layer 32a and the light transmitting layer 32b in the embodiment.

The contact hole 33 and the contact plug 31 each have an inverted truncated quadrangular pyramid shape. Therefore, an upper surface side of the contact plug 31 is thicker than a lower surface side. Note that the shape of each of the contact hole 33 and the contact plug 31 may be an inverted truncated cone.

An aspect ratio of the contact hole 33 is about twice large as an aspect ratio of other contact holes, for example, the contact hole 43.

In the embodiment, since a depth L of the contact hole 33 is about 5 to 10 μm, and an inner diameter D of the contact hole 33 is about 1 μm. Thus, an aspect ratio L/D is about 5 to 10.

The contact hole 33 extends through the lens layer 34 and the light transmitting layer 32, and exposes the relay layer 30 at a bottom of the contact hole 33.

At the relay layer 30, the contact hole 33 extends through a metal material layer 30a and an insulating material layer 30b of the relay layer 30 and exposes a metal material layer 30c of the relay layer 30.

A lower surface of the contact plug 31 provided at the contact hole 33 is in contact with the metal material layer 30c of the relay layer 30. Thus, the relay layer 30 and the contact plug 31 are electrically connected to each other.

The relay layer 30 includes the metal material layer 30a, the insulating material layer 30b and the metal material layer 30c provided sequentially from the pixel electrode 10 side.

The metal material layer 30a contains a metal material. In the embodiment, the metal material layer 30a is a single-layered conductive layer made of a conductive material containing tungsten silicide (WSi) or a single-layered conductive layer made of a conductive material containing titanium nitride. Note that as will be described in detail later, the metal material layer 30a functions as an etching stopper when the contact hole 33 is formed by etching.

The insulating material layer 30b contains an insulating material. In the embodiment, the insulating material layer 30b is an insulating layer made of oxide silicon (SiO 2). Note that, although details will be described later, the insulating material layer 30b functions as an etching stopper when an etching mask used for forming the contact hole 33 is removed. The insulating material layer 30b may be made of silicon nitride (SiN).

The metal material layer 30c contains a metal material. In the embodiment, the metal material layer 30c is a three-layered conductive layer in which metal materials of titanium nitride, aluminum and titanium nitride are stacked. Note that the metal material layer 30c may be a single-layered conductive layer made of a conductive material containing tungsten (W).

The contact hole 33 is provided at a position overlapping the contact plug 41. This facilitates etching control. Because, the bottom of the contact hole 33 is formed at the contact plug 41 even when the contact hole 33 extends through the relay layer 30 due to overetching. Therefore, the contact plug 31 filled at the contact hole 33 is in direct contact with the contact plug 41, and is electrically connected to the contact plug 41.

1.6. Method of Manufacturing Optical Functional Layer

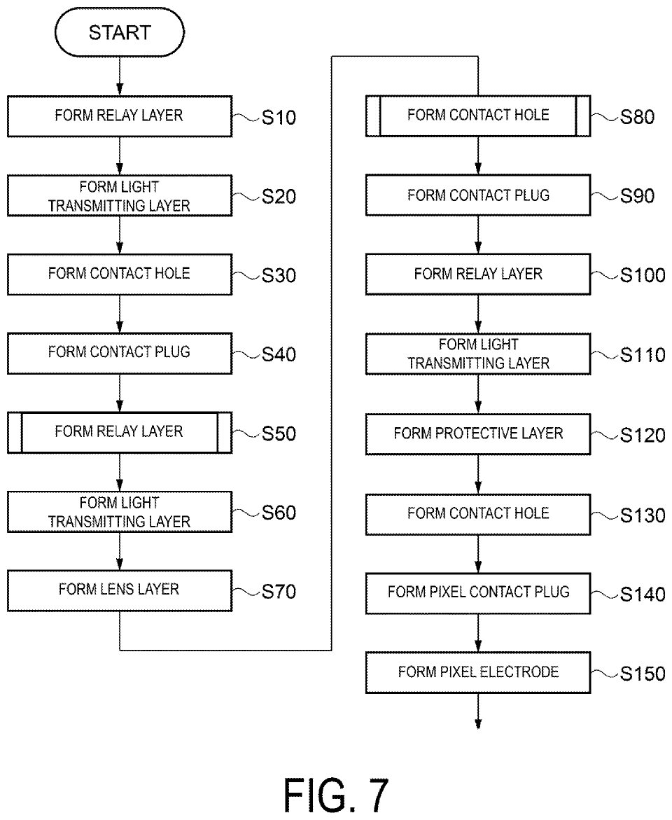

Next, a method of manufacturing the optical functional layer LS of the element substrate 100 in the liquid crystal device 300 will be described with reference to FIGS. 7 to 13.

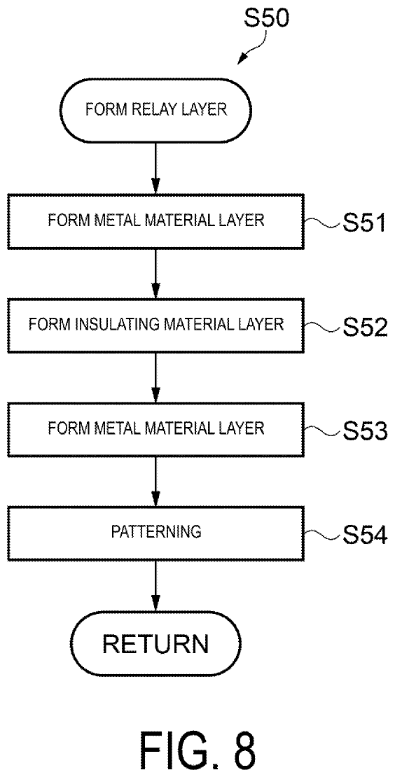

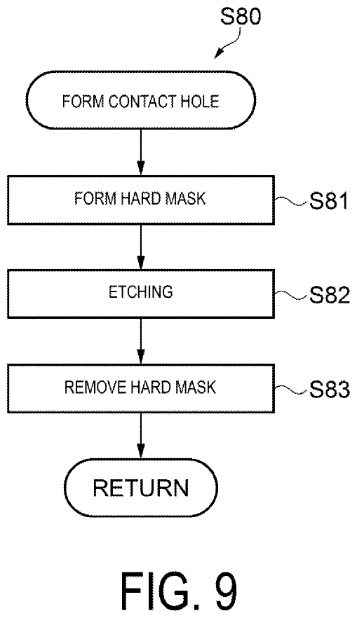

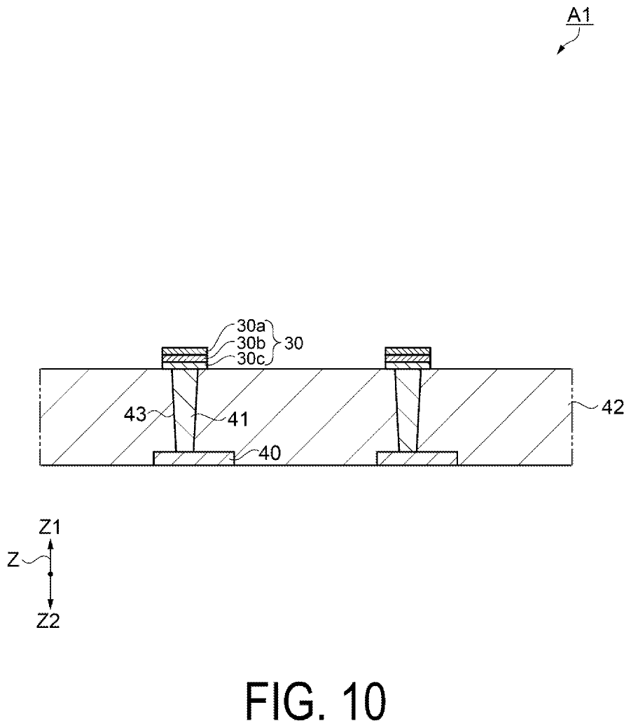

FIG. 7 is a flowchart illustrating the method of manufacturing the optical functional layer LS. FIG. 8 is a detailed flowchart of step S50 in the flowchart of FIG. 7. FIG. 9 is a detailed flowchart of step S80 in the flowchart of FIG. 7. FIGS. 10 to 13 are each a cross-sectional view illustrating an aspect in each manufacturing process, and a cross-sectional position in each drawing is the same as that in FIG. 6.

In Step S10, the capacitor electrode 40 as a relay layer is formed. The capacitor electrode 40 is formed by forming a conductive material containing titanium nitride as film at the dielectric layer 56 and then patterning the film.

In step S20, the light transmitting layer 42 made of oxide silicon is formed at the capacitance electrode 40.

In Step S30, the contact hole 43 is formed at the light transmitting layer 42.

In step S40, the contact hole 43 is filled with a conductive material containing tungsten to form the contact plug 41.

In step S50, the relay layer 30 is formed. The relay layer 30 is provided at a position overlapping the contact plug 41 in plan view.

Details of step S50 will be described with reference to FIG. 8.

In step S51, titanium nitride, aluminum and titanium nitride to be the metal material layer 30c are each formed as film in this order.

In step S52, oxide silicon to be the insulating material layer 30b is formed as film at the metal material layer 30c.

In step S53, titanium nitride or tungsten silicide to be the metal material layer 30a is formed at the insulating material layer 30b.

In step S54, the relay layer 30 is formed. The metal material layer 30a, the insulating material layer 30b and the metal material layer 30c are collectively patterned to form the relay layer 30 in contact with the contact plug 41 as illustrated in FIG. 10.

Returning to FIG. 7, in step S60, the light transmitting layer 32 is formed.

The light transmitting layer 32 is formed in two film forming processes. The light transmitting layer 32a is formed as film in a first film forming process, and the light transmitting layer 32b is formed as film in a second film forming process.

The light transmitting layer 32 is formed to have a thickness of about 7 μm by the two film forming processes.

Thereafter, the light transmitting layer 32 is etched to form the concave portion 32c at the light transmitting layer 32.

In step S70, the lens layer 34 is formed. The lens layer 34 is formed of an inorganic material having a refractive index different from that of the light transmitting layer 32, for example, silicon oxynitride.

The lens layer 34 is planarized by CMP or the like after silicon oxynitride is formed as film as to fill the concave portion 32c.

In step S80, the contact hole 33 is formed. Details of step S80 will be described with reference to FIG. 9.

In step S81, a hard mask 110 is formed.

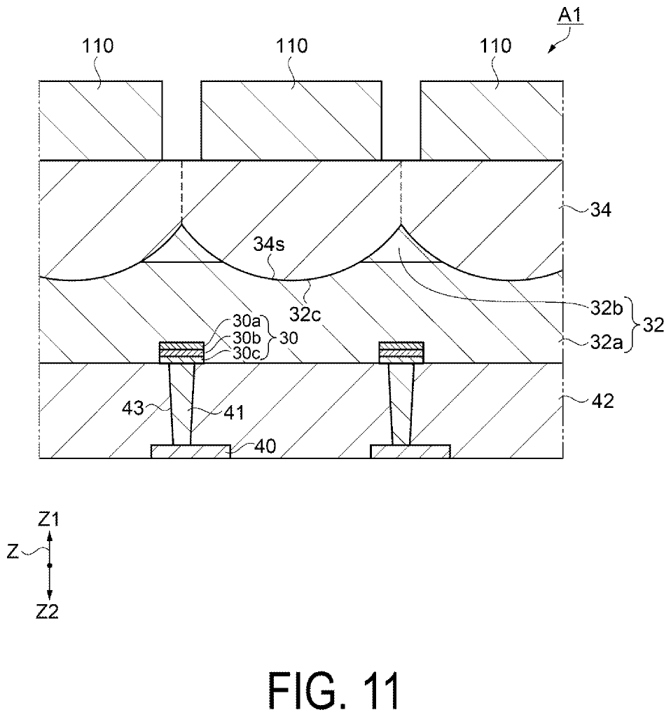

After a mask layer containing a metal material is formed at the lens layer 34, the mask layer is patterned to form the hard mask 110 as an etching mask including an opening at a position where the contact hole 33 is to be formed as illustrated in FIG. 11. In the embodiment, the hard mask 110 contains tungsten silicide.

By using the hard mask 110 as an etching mask, the contact hole 33 having a high aspect ratio can be formed more easily than in a case of using a resist mask.

Furthermore, by forming the hard mask 110 with the same metal material as that of the metal material layer 30a, it is possible to easily remove the metal material layer 30a at the bottom of the contact hole 33a and expose the metal material layer 30c of the relay layer 30 at the bottom of the contact hole 33 in a process of removing the hard mask 110 to be described later.

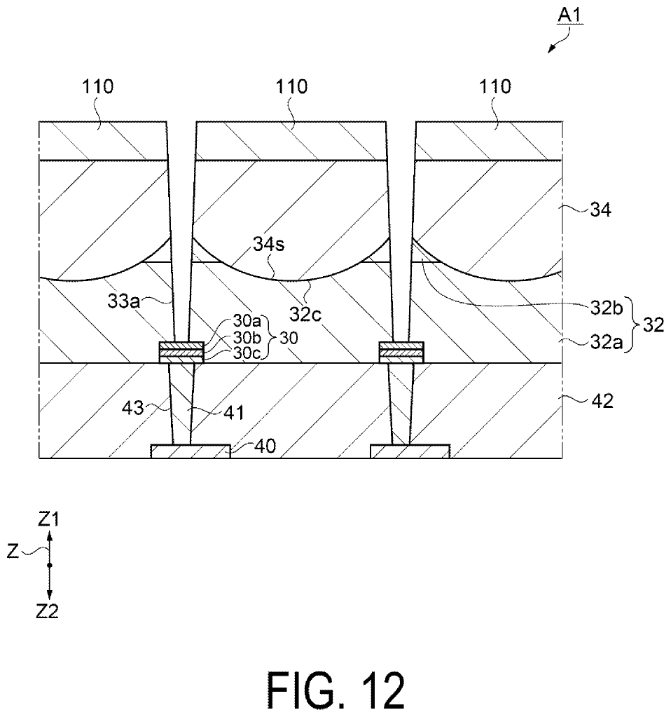

In step S82, etching is performed. The contact hole 33a is formed by performing dry etching on the lens layer 34 and the light transmitting layer 32 using the hard mask 110. As illustrated in FIG. 12, the metal material layer 30a of the relay layer 30 is exposed at the bottom of the contact hole 33a.

Tungsten silicide or titanium nitride contained in the metal material layer 30a has etching resistance against an etchant for etching the lens layer 34 and the light transmitting layer 32. Therefore, the etching for forming the contact hole 33a is temporarily stopped at a position where the metal material layer 30a of the relay layer 30 is exposed.

In other words, the metal material layer 30a contains a material having a lower etching rate with respect to an etchant for etching the lens layer 34 and the light transmitting layer 32 than that of the lens layer 34 and the light transmitting layer 32, and functions as an etching stopper in the process of forming the contact hole 33a.

In step S83, the hard mask 110 is removed.

By etching for removing the hard mask 110, the metal material layer 30a at the bottom of the contact hole 33 is removed together with the hard mask 110.

After the metal material layer 30a is removed, the insulating material layer 30b is etched.

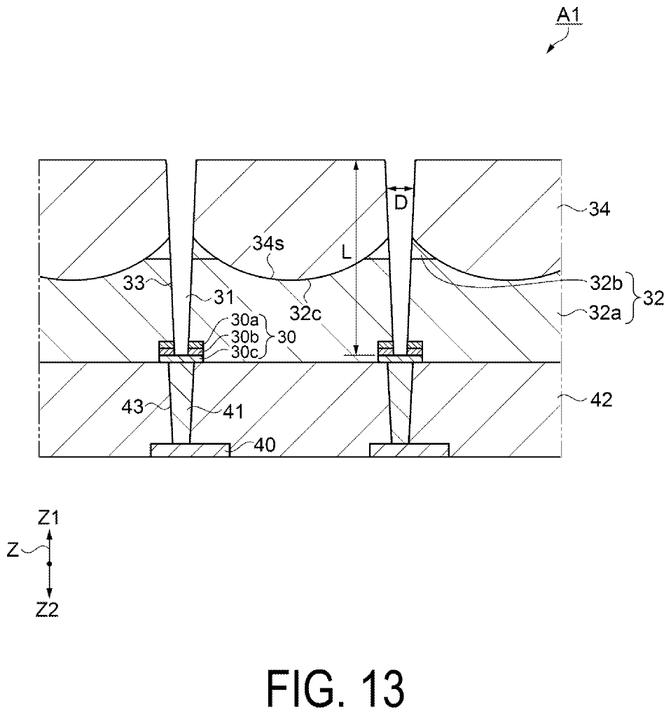

When the etching of the insulating material layer 30b is taken into consideration, in the process of removing the hard mask 110, as illustrated in FIG. 13, the contact hole 33 can be made to extend through the metal material layer 30a and the insulating material layer 30b of the relay layer 30 to expose the metal material layer 30c of the relay layer 30 at the bottom of the contact hole 33.

Tungsten silicide or titanium nitride contained in the metal material layer 30a has a high etching rate with respect to an etchant for removing the hard mask 110, thus is removed at the same time when the hard mask 110 is removed.

The insulating material layer 30b contains a material having a low etching rate with respect to the etchant for removing the hard mask 110. Therefore, after the metal material layer 30a disappears, the insulating material layer 30b exposed at the bottom of the contact hole 33 is slowly etched. In other words, the insulating material layer 30b functions as an etching stopper in the process of forming the contact hole 33a.

By adjusting a thickness/thicknesses of the metal material layer 30a and/or the insulating material layer 30b, the metal material layer 30c can be exposed at the bottom of the contact hole 33 at the same time as the end of the process of removing the hard mask 110. Note that when the insulating material layer 30b remains at the bottom of the contact hole 33, the insulating material layer 30b may be removed by performing etchback after the process of removing the hard mask 110.

Reference is now made back to FIG. 7.

In Step S90, the contact plug 31 is formed. The contact hole 33 is filled with a conductive material containing tungsten to form the contact plug 31.

In the embodiment, since the metal material layer 30c of the relay layer 30 is exposed at the bottom of the contact hole 33, the contact plug 31 is in contact with the metal material layer 30c, and the contact plug 31 and the relay layer 30 are electrically connected to each other.

In Step S100, the relay layer 20 is formed. As illustrated in FIG. 6, the relay layer 20 made of a conductive material containing titanium nitride and aluminum, or a conductive material containing tungsten is formed at the contact plug 31.

In step S110, the light transmitting layer 22 formed of oxide silicon is formed at the relay layer 20.

In step S120, the protective layer 24 is formed. The protective layer 24 is formed of BSG.

In Step S130, the contact hole 23 that extends through the protective layer 24 and the light transmitting layer 22 and exposes the relay layer 20 is formed.

In step S140, the pixel contact plug 21 is formed. An inside of the contact hole 23 is filled with a conductive material containing tungsten to form the pixel contact plug 21.

In step S150, the pixel electrode 10 is formed. The pixel electrode 10 is formed at the protective layer 24 so as to be in contact with an upper surface of the pixel contact plug 21.

1.7. Modifications

The above-described embodiment may be variously modified. Specific modified aspects which may be applied to the embodiment described above will be illustrated below. Two or more aspects freely selected from the following examples may be appropriately combined as long as the examples do not contradict each other.

1.7.1. Modification 1

In Modification 1, the metal material layer 30a of the relay layer 30 is a single-layered conductive layer made of a conductive material containing tungsten (W).

The insulating material layer 30b of the relay layer 30 is an insulating layer made of oxide silicon or silicon nitride.

The metal material layer 30c of the relay layer 30 is a single-layered conductive layer made of a conductive material containing tungsten. Note that the metal material layer 30c may be a three-layered conductive layer in which metal materials of titanium nitride, aluminum and titanium nitride are stacked.

When a metal material containing tungsten is used for the metal material layer 30a of the relay layer 30, the metal material containing tungsten may also be used similarly for the hard mask 110.

By forming the hard mask 110 and the metal material layer 30a of the relay layer 30 with the same metal material containing tungsten, the contact hole 33 having a high aspect ratio can be easily formed in the process of removing the hard mask 110. More specifically, in the process of removing the hard mask 110, it is possible to easily remove the metal material layer 30a and the insulating material layer 30b remaining at the bottom of the contact hole 33a, and to expose the metal material layer 30c of the relay layer 30 at the bottom of the contact hole 33.

1.7.2. Modification 2

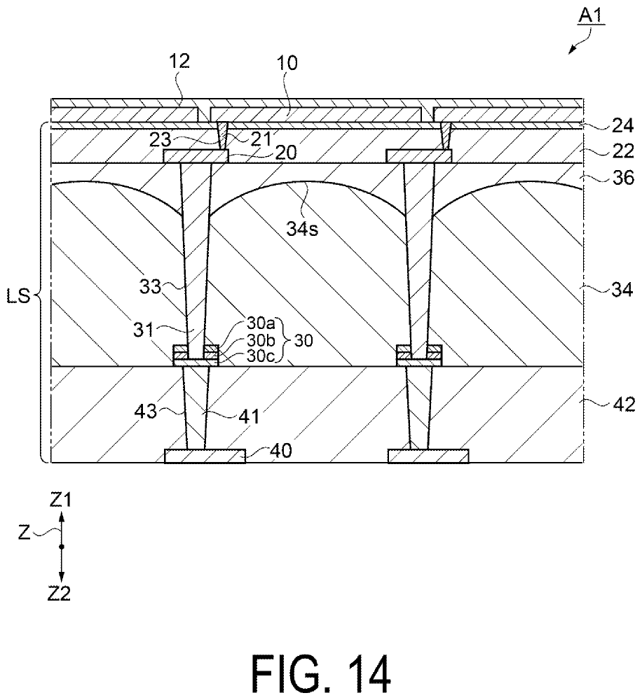

FIG. 14 is a cross-sectional view of an electro-optical device according to Modification 2, and illustrates a cross-sectional structure of the optical functional layer LS of the element substrate 100, similarly to FIG. 6.

In Modification 2, the lens layer 34 is provided at the light transmitting layer 42. The lens layer 34 includes a lens surface 34s protruding toward the pixel electrode 10.

A light transmitting layer 36 is provided at the lens surface 34s of the lens layer 34.

An upper surface of the light transmitting layer 36 is planarized.

In Modification 2, the hard mask 110 is provided at the light transmitting layer 36. In addition, the contact hole 33 extends through the light transmitting layer 36 and the lens layer 34, extends through the metal material layer 30a and the insulating material layer 30b of the relay layer 30, and exposes the metal material layer 30c of the relay layer 30 at the bottom of the contact hole 33.

The contact plug 31 is provided at the contact hole 33. The contact plug 31 electrically connects the relay layer 20 and the metal material layer 30c of the relay layer 30.

As described above, the liquid crystal device 300 as the electro-optical device of the embodiment includes the transistor 1, the pixel electrode 10 provided corresponding to the transistor 1, the relay layer 30 provided at the layer between the transistor 1 and the pixel electrode 10 and including the metal material layer 30a containing a metal material, the insulating material layer 30b containing an insulating material, and the metal material layer 30c containing a metal material in this order from the pixel electrode 10 side, and the lens layer 34 provided at the layer between the relay layer 30 and the pixel electrode 10 and including the contact hole 33 for electrically connecting the relay layer 30 and the pixel electrode 10, wherein in the relay layer 30, portions of the metal material layer 30a and the insulating material layer 30b overlapping the contact hole 33 are removed.

As described above, the relay layer 30 includes the metal material layer 30a containing a metal material, the insulating material layer 30b containing an insulating material, and the metal material layer 30c containing a metal material in this order from the pixel electrode 10 side, and portions of the metal material layer 30a and the insulating material layer 30b overlapping the contact hole 33 are removed.

In other words, the metal material layer 30c of the relay layer 30 is electrically connected to the pixel electrode 10 via the contact hole 33. That is, the relay layer 30 and the pixel electrode 10 can be reliably electrically connected to each other via the contact hole 33.

Furthermore, even when the contact hole 33 is formed by using the hard mask 110, the relay layer 30 can be prevented from disappearing. Further, by using the hard mask 110, the contact hole 33 having a high aspect ratio can be easily formed.

In addition, in the liquid crystal device 300 of the embodiment, the metal material layer 30a contains WSi or TiN, the insulating material layer 30b contains SiO₂ or SiN, and the metal material layer 30c contains TiN and AL. Alternatively, the metal material layer 30c contains W.

Therefore, in the contact hole 33, the relay layer 30 and the pixel electrode 10 can be electrically connected by the metal material layer 30c containing TiN and AL or W.

Furthermore, even when the contact hole 33 is formed by using the hard mask 110 made of a metal material containing WSi or TiN, the relay layer 30 can be prevented from disappearing.

Additionally, in the liquid crystal device 300 of the embodiment, the metal material layer 30a contains W, the insulating material layer 30b contains SiO₂ or SiN, and the metal material layer 30c contains W. Alternatively, the metal material layer 30c contains TiN and AL.

Therefore, in the contact hole 33, the relay layer 30 and the pixel electrode 10 can be electrically connected by the metal material layer 30c containing W, or TiN and AL.

Furthermore, even when the contact hole 33 is formed by using the hard mask 110 made of a metal material containing W, the relay layer 30 can be prevented from disappearing.

Additionally, the liquid crystal device 300 of the embodiment includes the relay layer 20 electrically connected to the relay layer 30 via the contact hole 33 at the layer between the lens layer 34 and the pixel electrode 10, and the light transmitting layer 22 including the contact hole 23 for electrically connecting the relay layer 20 and the pixel electrode 10 at the layer between the relay layer 20 and the pixel electrode 10, and the contact hole 33 and the contact hole 23 are provided so as not to overlap each other in plan view.

As described above, since the contact hole 33 and the contact hole 23 do not overlap each other in plan view, the contact hole 33 can be disposed at a gap between the adjacent pixels P, and a wide opening region through which light passes can be secured. Further, the film formability of the pixel electrode 10 can be improved.

The liquid crystal device 300 of the embodiment further includes the light transmitting layer 42 including the contact hole 43 for electrically connecting the relay layer 30 and the transistor 1, and the contact hole 43 and the contact hole 33 are provided so as to overlap each other in plan view.

As described above, since the contact hole 43 and the contact hole 33 are provided so as to overlap each other in plan view, even when the contact hole 33 extends through the relay layer 30 during formation of the contact hole 33, electrical conduction via the contact hole 33 can be achieved.

Therefore, the contact hole 33 can be easily formed.

Furthermore, it is possible to reduce a region shielded from light with the contact hole 33 and the contact hole 43, and a wider opening region through which light passes can be secured.

The liquid crystal device 300 of the embodiment further includes the contact plug 31, the pixel contact plug 21 and the contact plug 41 as connecting members at the contact hole 33, the contact hole 23 and the contact hole 43, respectively.

According to the configuration of the liquid crystal device 300 of the embodiment, since the hard mask 110 can be used to form the contact hole 33, the contact hole 33 having a high aspect ratio can be formed with high quality. Since the quality of the contact hole 33 is improved, quality of the contact plug 31 formed at the contact hole 33 is also improved. Therefore, it is possible to improve reliability of electrical connecting between the pixel electrode 10 and the transistor 1.

A method of manufacturing the liquid crystal device 300 as the electro-optical device of the embodiment includes forming the relay layer 30, forming the lens layer 34 at the relay layer 30, forming the hard mask 110 containing a metal material at the lens layer 34, forming the contact hole 33 at the lens layer 34 via the hard mask 110, and removing the hard mask 110, wherein the relay layer 30 includes the metal material layer 30a containing a metal material, the insulating material layer 30b containing a material having a lower etching rate with respect to an etchant for removing the hard mask 110 than that of the hard mask 110, and the metal material layer 30c containing a metal material, wherein in the process of removing the hard mask 110, the metal material layer 30a and the insulating material layer 30b are partially removed.

As described above, since the relay layer 30 includes the metal material layer 30a containing a metal material, the insulating material layer 30b containing an insulating material having a lower etching rate with respect to an etchant for removing the hard mask than that of the hard mask 110, and the metal material layer 30c containing a metal material, even when the contact hole 33 is formed using the hard mask 110, the relay layer 30 can be prevented from disappearing.

Further, by using the hard mask 110, the contact hole 33 having a high aspect ratio can be easily formed.

In addition, in the method of manufacturing the liquid crystal device 300 of the embodiment, the hard mask 110 contains WSi, and the relay layer 30 contains WSi or Ti.

As described above, by forming the hard mask 110 and the metal material layer 30a of the relay layer 30 with the same metal material containing WSi, the contact hole 33 having a high aspect ratio can be easily formed. More specifically, in the process of removing the hard mask 110, it is possible to easily remove the metal material layer 30a exposed at the bottom of the contact hole 33a, and expose the metal material layer 30c of the relay layer 30 at the bottom of the contact hole 33.

In addition, in the method of manufacturing the liquid crystal device 300 of the embodiment, the hard mask 110 contains W, and the relay layer 30 contains W.

As described above, by forming the hard mask 110 and the metal material layer 30a of the relay layer 30 with the same metal material containing W, the contact hole 33 having a high aspect ratio can be easily formed. More specifically, in the process of removing the hard mask 110, it is possible to easily remove the metal material layer 30a exposed at the bottom of the contact hole 33a, and expose the metal material layer 30c of the relay layer 30 at the bottom of the contact hole 33.

The method of manufacturing the liquid crystal device 300 of the embodiment further includes filling the contact hole 33 with the contact plug 31, and forming the relay layer 20 so as to be in contact with the contact plug 31.

In the method of manufacturing the liquid crystal device 300 of the embodiment, since the contact hole 33 is formed using the hard mask 110, the contact hole 33 having a high aspect ratio can be formed with high quality. Therefore, the quality of the contact plug 31 formed at the contact hole 33 is also improved, and it is possible to improve the reliability of electrical connecting between the pixel electrode 10 and the transistor 1.

The method of manufacturing the liquid crystal device 300 of the embodiment further includes forming the light transmitting layer 22 at the relay layer 20, forming the contact hole 23 at a position not overlapping the contact hole 33 of the light transmitting layer 22, filling the contact hole 23 with the pixel contact plug 21, and forming the pixel electrode 10 so as to be in contact with the pixel contact plug 21.

As described above, since the contact hole 33 and the contact hole 23 are formed so as not to overlap each other in plan view, it is possible to improve the film formability of the pixel electrode 10. Further, the contact hole 33 can be disposed at a gap between the adjacent pixels P, and a wide opening region through which light passes can be secured.

### 2. Embodiment 2

2.1. Structure of Display Region of Element Substrate

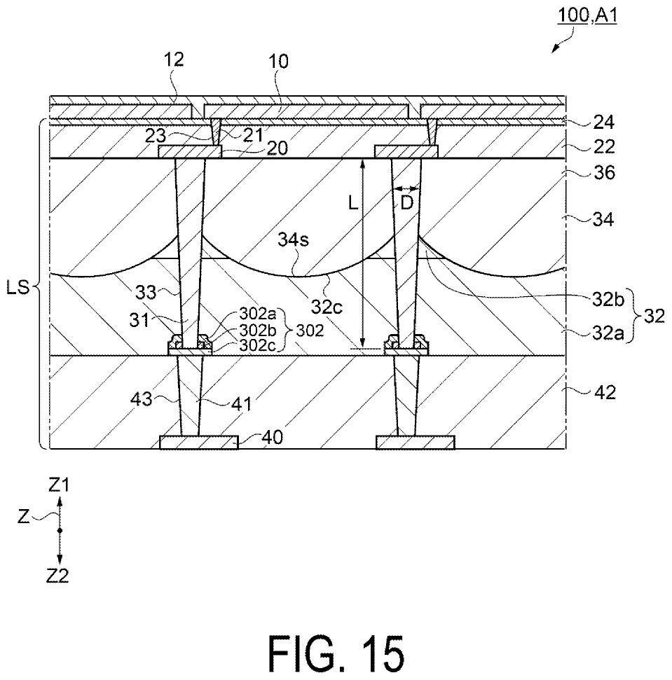

A structure of the liquid crystal device 300 as an electro-optical device according to Embodiment 2 will be described with reference to FIG. 15.

FIG. 15 is a cross-sectional view of the electro-optical device according to Embodiment 2, and illustrates a cross-sectional structure of the optical functional layer LS in the display region A1 of the element substrate 100. A cross-sectional position of FIG. 15 is the same as that of FIG. 6.

In Embodiment 2, a configuration of a relay layer 302 is different from that of the relay layer 30 of Embodiment 1. The same reference numerals are given to the same configurations as in Embodiment 1, and the description thereof will be omitted.

As illustrated in FIG. 15, the relay layer 302 includes a metal material layer 302a, an insulating material layer 302b and a metal material layer 302c provided sequentially from the pixel electrode 10 side.

The insulating material layer 302b is provided in an island shape at a position overlapping the contact hole 33.

The contact hole 33 extends through the insulating material layer 302b. The contact hole 33 is provided at a position where an entire periphery thereof is surrounded by the insulating material layer 302b in plan view.

The metal material layer 302a and the metal material layer 302c are in contact with each other on an outer side of the insulating material layer 302b and are electrically connected to each other. Therefore, since the metal material layer 302a exposed to an inner wall of the contact hole 33 is in contact with the contact plug 31, reliability of electrical connecting between the relay layer 302 and the pixel electrode 10 can be improved.

The metal material layer 302a contains a metal material. In the embodiment, the metal material layer 302a is a single-layered conductive layer made of a conductive material containing tungsten silicide, titanium nitride or tungsten. Note that the metal material layer 302a functions as an etching stopper when the contact hole 33 is formed by etching.

The insulating material layer 302b contains an insulating material. In the embodiment, the insulating material layer 302b is an insulating layer made of oxide silicon or silicon nitride. Note that the insulating material layer 302b functions as an etching stopper when the hard mask 110 used for forming the contact hole 33 is removed.

The metal material layer 302c is formed of a metal material. In the embodiment, the metal material layer 302c is a three-layered conductive layer in which metal materials of titanium nitride, aluminum and titanium nitride are stacked. Note that the metal material layer 302c may be a single-layered conductive layer made of a conductive material containing tungsten.

2.2. Method of Manufacturing Optical Functional Layer

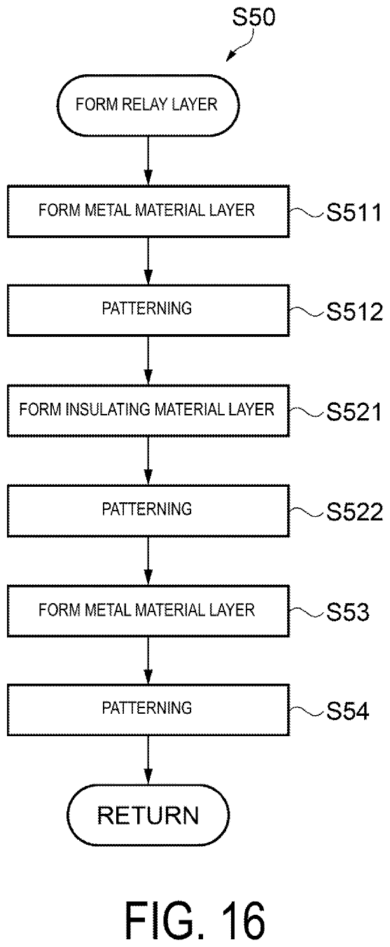

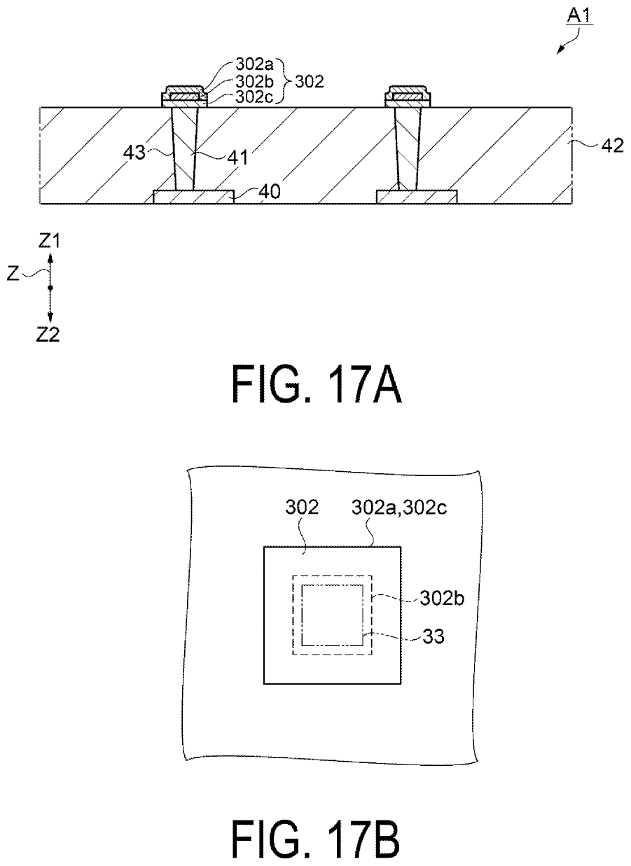

Next, a method of manufacturing the optical functional layer LS of the element substrate 100 in the liquid crystal device 300 of Embodiment 2 will be described with reference to FIGS. 16 to 17B.

FIG. 16 is a detailed flowchart of step S50 in the flowchart of FIG. 7. FIG. 17A is a cross-sectional view illustrating an aspect in a manufacturing process, and a cross-sectional position of FIG. 17A is the same as that in FIG. 6. FIG. 17B is a plan view illustrating an aspect in a manufacturing process.

In the embodiment, step S50 in the flowchart of FIG. 7 is different from that in Embodiment 1. Since steps S10 to S40 and steps S60 to S150 are the same as those in Embodiment 1, the description thereof will be omitted.

As illustrated in FIG. 16, in step S511, the metal material layer 302c is formed.

In this process, titanium nitride, aluminum and titanium nitride to be the metal material layer 302c are each formed as film in this order. The metal material layer 302c may be a single-layered conductive layer containing tungsten.

In step S512, the metal material layer 302c is patterned.

In step S521, oxide silicon or silicon nitride to be the insulating material layer 302b is formed as film.

In the step S522, the insulating material layer 302b is patterned. The insulating material layer 302b is patterned to have a smaller size in plan view than that of the metal material layer 302c.

In step S53, titanium nitride or tungsten silicide to be the metal material layer 302a is formed as film. Note that when tungsten is used for the metal material layer 302c, it is good that tungsten is used for the metal material layer 302a.

In step S54, the metal material layer 302a is patterned. Note that at this time, the metal material layer 302c may be patterned at the same time.

By step S54, the relay layer 302 as illustrated in FIG. 17A is formed.

FIG. 17B is a plan view of the relay layer 302 of FIG. 17A. As illustrated in FIG. 17B, the insulating material layer 302b is provided in an island shape at a position overlapping the contact hole 33. An island shape refers to a state in which the insulating material layer 302b is surrounded by the metal material layer 302a and/or the metal material layer 302c.

The contact hole 33 is provided inside the insulating material layer 302b having an island shape. The position where the contact hole 33 is provided is indicated by a two-dot chain line.

As described above, according to the liquid crystal device 300 as the electro-optical device of the embodiment, the following effects can be obtained in addition to the effects of the above embodiment.

In addition, in the liquid crystal device 300 of the embodiment, the insulating material layer 302b is provided in an island shape at a position overlapping the contact hole 33.

In other words, the metal material layer 302a and the metal material layer 302c are in contact with each other around the insulating material layer 302b and are electrically connected to each other. Therefore, the reliability of electrical connecting between the relay layer 302 and the pixel electrode 10 can be improved.

In addition, in the method of manufacturing the liquid crystal device 300 of the embodiment, in the process of forming the relay layer 302, the insulating material layer 302b is formed in an island shape at a position overlapping the contact hole 33.

Therefore, the insulating material layer 302b can be caused to function as an etching stopper when the hard mask 110 used when the contact hole 33 is formed is removed. Therefore, the contact hole 33 having a high aspect ratio can be easily formed.

### 3. Embodiment 3

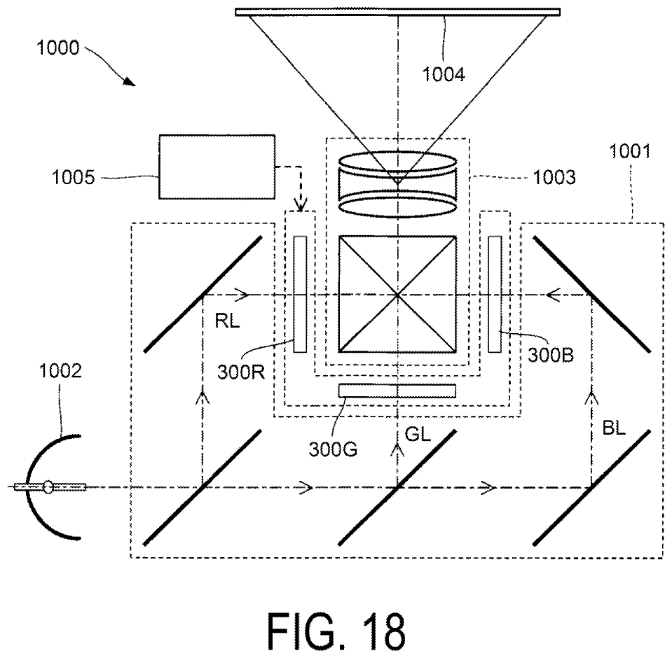

FIG. 18 is a schematic diagram illustrating a projector as a projection display device, which is an example of an electronic apparatus.

A projector 1000 is, for example, a three plate type projector including the three liquid crystal devices 300 described above. A liquid crystal device 300R corresponds to a red display color, a liquid crystal device 300G corresponds to a green display color, and a liquid crystal device 300B corresponds to a blue display color. A control unit 1005 includes, for example, a processor and a memory, and controls operations of the liquid crystal devices 300R, 300G, and 300B.

An illumination optical system 1001 supplies a red element RL of light emitted from an illumination device 1002 as a light source to the liquid crystal device 300R, a green element GL of the light to the liquid crystal device 300G, and a blue element BL of the light to the liquid crystal device 300B. The liquid crystal devices 300R, 300G, and 300B function as light modulation devices that modulate color light RL, GL, and BL supplied from the illumination optical system 1001 according to a display image, respectively.

A projection optical system 1003 combines emission light from each of the liquid crystal devices 300R, 300G, and 300B and projects the combined light onto a projector screen 1004.

As described above, the projector 1000 as the electronic apparatus according to the embodiment includes the liquid crystal device 300 described above.

Therefore, it is possible to improve performance of the projector 1000 by adopting the liquid crystal device 300 having high optical performance and high electrical reliability.

The electronic apparatus is not limited to the illustrated three plate type projector 1000. For example, the projector may be a single plate type projector, a double plate type projector, or a projector including four or more liquid crystal devices 300. Further, the electronic apparatus may be personal digital assistants (PDA), digital still cameras, televisions, video cameras, car navigation apparatuses, in-vehicle displays, electronic organizers, electronic paper, calculators, word processors, workstations, videophones, point-of-sale (POS), printers, scanners, copiers, video players, or equipment including a touch panel.

Although preferred embodiments have been described above, the present disclosure is not limited to the above-described embodiments. In addition, the configuration of each component of the present disclosure may be replaced with any configuration that exerts the equivalent functions of the above-described embodiments, and to which any configuration may be added.

What is claimed is:

1. An electro-optical device, comprising:
a transistor;
a pixel electrode provided corresponding to the transistor;
a first conductive layer provided at a layer between the transistor and the pixel electrode, and including a first layer containing a metal material, a second layer containing an insulating material, and a third layer containing a metal material in this order from the pixel electrode side; and
a lens layer provided at a layer between the first conductive layer and the pixel electrode, and including a first contact hole for electrically connecting the first conductive layer and the pixel electrode, wherein
in the first conductive layer, portions of the first layer and the second layer overlapping the first contact hole are removed.

2. The electro-optical device according to claim 1, wherein
the first layer contains WSi or TiN,
the second layer contains SiO₂ or SiN, and
the third layer contains TiN and AL, or contains W.

3. The electro-optical device according to claim 1, wherein
the first layer contains W,
the second layer contains SiO₂ or SiN, and
the third layer contains W, or contains TiN and AL.

4. The electro-optical device according to claim 1, wherein
the second layer is provided in an island shape at a position overlapping the first contact hole.

5. The electro-optical device according to claim 1, comprising:
a second conductive layer electrically connected to the first conductive layer via the first contact hole at a layer between the lens layer and the pixel electrode; and
a light transmitting layer including a second contact hole for electrically connecting the second conductive layer and the pixel electrode at a layer between the second conductive layer and the pixel electrode, wherein
the first contact hole and the second contact hole are provided so as not to overlap each other in plan view.

6. The electro-optical device according to claim 5, comprising a third light transmitting layer including a third contact hole for electrically connecting the first conductive layer and the transistor, wherein
the third contact hole and the first contact hole are provided so as to overlap each other in plan view.

7. The electro-optical device according to claim 6, wherein
a connecting member is included at each of the first contact hole, the second contact hole and the third contact hole.

8. An electronic apparatus comprising the electro-optical device according to claim 1.
